(19) United States
(12) Patent Application Publication
(10) Pub. No.: US 2012/0021252 A1
(43) Pub. Date: Jan. 26, 2012

(54) Treating Surface of Substrate Using Inert Gas Plasma in Atomic Layer Deposition

(75) Inventor: Sang In LEE, Sunnyvale, CA (US)

(73) Assignee: SYNOS TECHNOLOGY, INC., Sunnyvale, CA (US)

(21) Appl. No.: 13/185,793

(22) Filed: Jul. 19, 2011

Related U.S. Application Data
(60) Provisional application No. 61/366,906, filed on Jul. 22, 2010.

(51) Int. Cl. C01F 7/02; H05H 1/00; B32B 9/00; C23C 16/50

(52) U.S. Cl. 428/702; 118/719; 423/625; 427/535

(57) ABSTRACT

Depositing one or more layers of material on a substrate using atomic layer deposition (ALD) followed by surface treating the substrate with radicals of inert gas before subjecting the substrate to further deposition of layers. The radicals of the inert gas appear to change the surface state of the deposited layer to a state more amenable to absorb subsequent source precursor molecules. The radicals of the inert gas disconnect bonding of molecules on the surface of the substrate, and render the molecules on the surface to have dangling bonds. The dangling bonds facilitate absorption of subsequently injected source precursor molecules into the surface. Exposure to the radicals of the inert gas thereby increases the deposition rate and improves the properties of the deposited layer.

### CROSS-REFERENCE TO RELATED APPLICATION

This application claims priority under 35 U.S.C. §119(e) to co-pending U.S. Provisional Patent Application No. 61/366,906, filed on Jul. 22, 2010, which is incorporated by reference herein in its entirety.

### BACKGROUND

1. Field of Art

The present invention relates to increasing deposition rate in the process of performing atomic layer deposition (ALD) by treating surface of a substrate with radicals of inert gas.

2. Description of Related Art

In general, a reactor for atomic layer deposition (ALD) injects source precursor and reactant precursor alternately onto a substrate. ALD uses the bonding force of a chemisorbed layer that is different from the bonding force of a physisorbed layer. In ALD, a precursor is absorbed into the surface of a substrate and then purged with an inert gas. As a result, physisorbed molecules of the precursor (bonded by the Van der Waals force) are desorbed from the substrate. However, chemisorbed molecules of the precursor are covalently bonded, and hence, these molecules are strongly adsorbed in the substrate and not desorbed from the substrate. ALD is performed using the properties that the chemisorbed molecules of the precursor (adsorbed in the substrate) react and/or replace a reactant precursor.

More specifically, a source precursor is injected into a chamber so that the source precursor is excessively adsorbed on a substrate. Then, the excessive precursor or physisorbed molecules are removed by injecting a purge gas and/or pumping the chamber, causing only chemisorbed molecules to remain on the substrate. The chemisorbed molecules results in a mono molecule layer. Subsequently, a reactant precursor (or replacement agent) is injected into the chamber. Then, the excessive precursor or physisorbed molecules are removed by injecting the purge gas and/or pumping the chamber, obtaining a final atomic layer.

In ALD, the basic unit of process consists of these four processes (i.e., injection of source precursor, purging, injection of reactant precursor and another purging), usually referred to as a cycle. If a chemisorbed layer in a saturation state is obtained, a deposition rate of about 1 Å per cycle is obtained. However, when a precursor is not adsorbed on the substrate in the saturation state, a deposition rate is slower than about 1 Å per cycle. If the physisorbed molecule layer is not completely removed but a portion of the physisorbed molecule layer remains on the substrate, the deposition rate is increased.

Since only a thin layer is obtained per a single cycle, multiple cycles of ALD must be performed to obtain a layer of desired thickness. Reiteration of multiple cycles of ALD may increase the associated fabrication time, and hence, decrease the overall yield of the fabricated substrates. Hence, it is desirable to develop a process that increases the thickness of layers deposited over a single cycle of ALD.

### SUMMARY

Embodiments relate to depositing one or more layers of materials on a substrate by exposing the surface of the substrate to radicals of inert gas before exposing the surface to a subsequent material. By exposing the surface to radicals of inert gas, the surface exhibits properties amenable to attract and bind the subsequent material that the surface is exposed to. Hence, the exposure of the substrate to the radicals of inert gas increases deposition rate.

In one embodiment, the substrate is exposed to a first material and then a second material to form a layer. The first material may be source precursor in atomic layer deposition (ALD). The second material may be reactant precursor in ALD. The substrate is exposed to the radicals of the inert gas and then exposed to a third material. The third material may be identical to the first material.

In one embodiment, at least part of the radicals of the inert gas is reverted to inert state after being injected onto the surface. The reverted gas then functions as a purge gas that removes excess second material from the surface of the substrate.

In one embodiment, the first and second materials include Trimethylaluminium, and the second material include O* radicals. As a result of exposure to Trimethylaluminium and O* radicals, a layer of Al₂O₃ is formed on the surface.

In one embodiment, the surface of the substrate is exposed to purge gas to remove excess source precursor on the surface after exposing the surface of the substrate to the source precursor and before exposing the surface to the reactant precursor. Further, the surface of the substrate is exposed to purge gas to remove excess reactant precursor on the surface after exposing the surface to the reactant precursor to the radicals of the inert gas.

In one embodiment, the surface of the substrate is exposed to the third material within 6 seconds after being exposed to the radicals of the inert gas.

In one embodiment, the substrate is placed on a susceptor and moved in a vacuum chamber to expose the substrate to the first material, the second material, the radicals of the inert gas and the third material.

In one embodiment, an article is manufactured by depositing one or more layers of materials where the surface is exposed to radicals of inert gas before exposing the surface to a subsequent material.

Embodiments also relate to an apparatus for performing deposition of one or more layers of material on a substrate that exposes the surface of the substrate to radicals of inert gas before exposing the surface to a subsequent material. The subsequent material may be source precursor for performing an ALD process.

### BRIEF DESCRIPTION OF DRAWINGS

FIG. 1 is a flowchart illustrating a method of performing remote plasma assisted atomic layer deposition (ALD), according to one embodiment.

FIG. 2 is a schematic diagram illustrating an apparatus for performing remote plasma assisted ALD, according to one embodiment.

FIG. 3 is a cross-sectional diagram illustrating an injector including a remote plasma generator, according to one embodiment.

FIG. 4 is a cross-sectional diagram of an injector including a coaxial remote plasma generator and a purge gas injector, according to one embodiment.

FIG. 5 is a cross-sectional diagram of an injector including a remote plasma generator and a purge gas injector, according to one embodiment.

FIG. 6 is a diagram illustrating disposition of injectors, according to one embodiment.

### DETAILED DESCRIPTION OF EMBODIMENTS

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

In the drawings, like reference numerals in the drawings denote like elements. The shape, size and regions, and the like, of the drawing may be exaggerated for clarity.

Embodiments relate to depositing one or more layers of atomic layers on a substrate using atomic layer deposition (ALD) where the surface of the substrate is treated with radicals of inert gas before subjecting the substrate to further deposition of atomic layers. The exposure of the surface to the radicals of the inert gas appears to change the surface state of the deposited layer to a state more amenable to absorb and bind subsequent source precursor molecules. Exposure to the radicals of the inert gas may increase the deposition rate and improves the properties of the deposited layer.

An atomic layer deposition (ALD) described herein refers to a process of depositing a thin layer on a surface by exposing the surface to a sequence of chemical materials in gaseous states.

Source precursor described herein refers to a chemical material that is injected on the surface before another chemical material (i.e., reactant precursor) to form a layer using ALD.

Reactant precursor described herein refers to a chemical material that is injected on the surface after another chemical material (i.e., source precursor) to form a layer using ALD.

A substrate described herein refers to an object having an exposed surface onto which one or more layers of materials may be deposited. The substrate may have a flat surface or a non-planar surface (e.g., curved surface). The substrate may be rigid (e.g., semiconductor wafer) or flexible (e.g., textile). The substrate may have various shapes and configurations (e.g., circular shape or tubular shape).

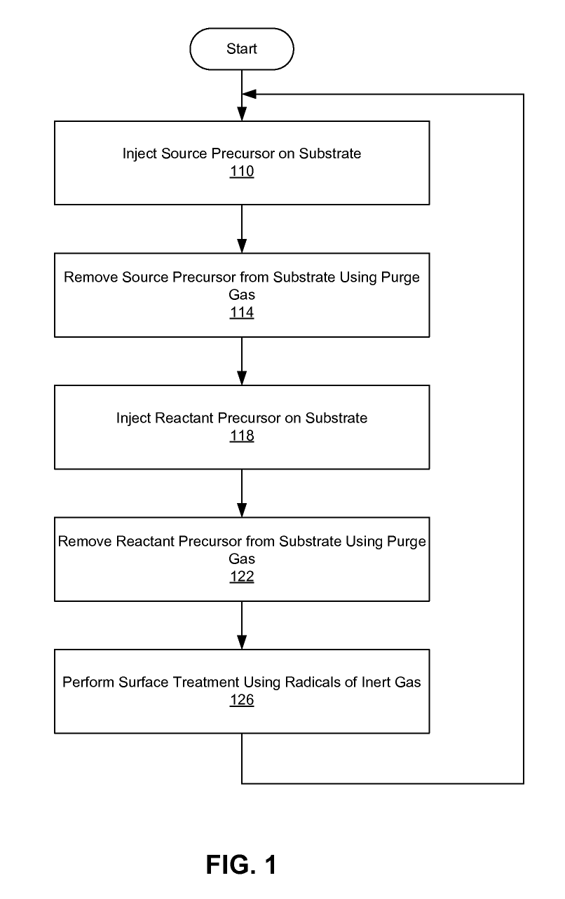

FIG. 1 is a flowchart illustrating a method of performing remote plasma assisted ALD, according to one embodiment. First, source precursor is injected 110 onto the surface of a substrate to form a layer of precursor on the surface of the substrate. Then purge gas (e.g., inert gas) is injected onto the surface of the substrate to remove physisorbed source precursor molecules from the surface while retaining chemisorbed source precursor molecules on the substrate.

Reactant precursor is then injected 118 onto the surface of the substrate. The surface is again exposed to purge gas (e.g., inert gas) to remove 122 redundant reactant precursor from the surface. The molecules of reactant precursor react and/or replace the source precursor molecules to from a layer of deposited material. The purge gas removes physisorbed reactant precursor molecules from the surface and leaves behind the layer of deposited material.

The surface is then subject to radicals of inert gas (e.g., Ar) to perform 128 surface treatment. The radicals are generated at a plasma generate located away from the substrate (hence, the process is referred to as “remote plasma assisted ALD”). Generating the radicals at a location away from the substrate is advantageous, among other reasons, because the substrate is not exposed to electric current that may cause damage or affect other devices formed on the substrate.

By treating the surface with radicals of inert gas, the molecules of the deposited layer on the surface of the substrates appears to have dangling bonds that attract and bind more source precursor molecules compared to the deposit layer not exposed to the radicals of inert gas. The dangling bonds facilitate the absorption of subsequently injected source precursor molecules into the surface, and hence, increase the deposition rate of the subsequent cycle of ALD.

If the thickness of the deposited layer is thinner than desired, the process returns to injecting 110 the surface of the substrate with source precursor. The steps of injecting 110 the surface of the substrate through performing 126 surface treatment using the radicals of inert gas may be repeated for multiple cycles until the desired thickness of deposited layer is obtained. The step of performing 126 surface treatment using the radicals of the inert gas may be omitted in the last cycle after the final layer is deposited.

It is advantageous to expose the surface of the substrate treated with the radicals of inert gas to the source precursor at an earlier time. The properties of the substrate treated with the radicals start to revert to a previous state (before exposure to the radicals) after the surface is exposed to the radicals of the inert gas.

The time when the surface starts to revert to the previous state and the speed at which such a reversal process takes place are dependent on factors such as the level of residual impurity in a processing chamber. If the processing chamber is under a high level of vacuum state, the surface treatment tends to last a longer period and revert at a slower speed since there are fewer residual impurities to interact with the treated surface. In contrast, if the processing chamber is in a low level of vacuum state, there are more residual impurities that may interact with the treated surface, causing the treated surface to revert to the previous state earlier at a higher speed. In one or more embodiments, the processing chamber is maintained at a vacuum state not higher than 1 mTorr. Under such level of vacuum state, the surface treated with the radicals of the inert gas is exposed to the source precursor within 10 seconds. In some embodiments, the surface treated with the radicals is subject to the source precursor within 3 seconds.

In one embodiment, the steps of injecting 110 source precursor on the substrate through removing 122 reactant precursor is repeated multiple times before performing 126 the surface treatment using the radicals of inert gas. By injecting source precursor multiple times on the substrate, more complete absorption of source precursors in a substrate can be achieved. Such multiple injections are advantageous in materials such as TiCl₄ which are not well absorbed in a substrate.

Exposing the surface of the substrate to the radicals of the inert gas has the benefits of, among others, (i) increasing the deposition rate, (ii) increasing the density of the deposited layer, (iii) enhancing the quality of the deposited layer (e.g., increase in index of the refraction of deposited layer) and (iv) achieves annealing effects of the deposited layer.

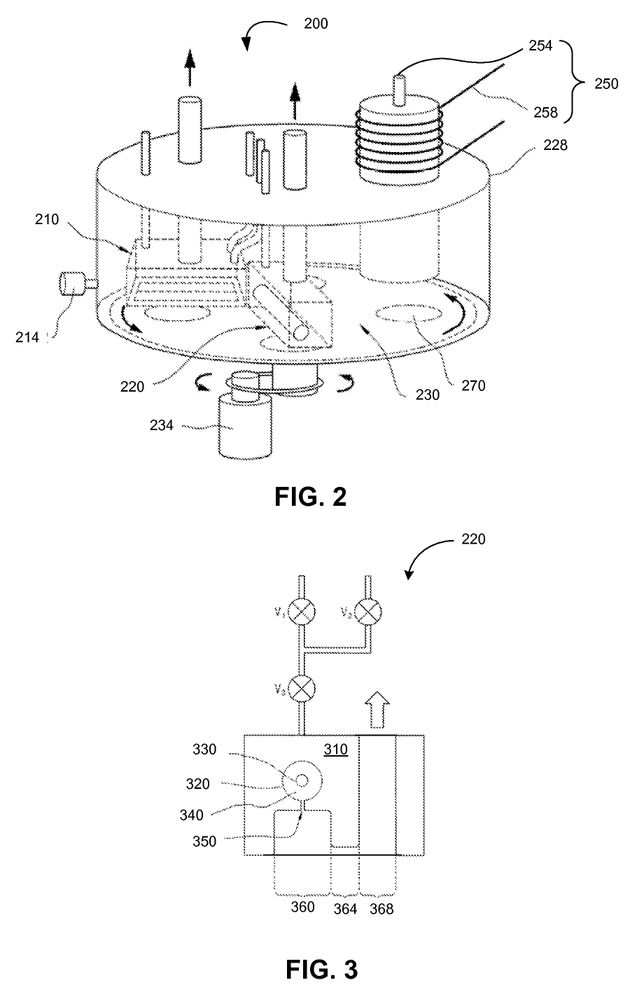

The processes illustrated in FIG. 1 can be performed in an apparatus 200 illustrated in FIG. 2. FIG. 2 is a schematic view of an apparatus 200 for performing remote plasma assisted ALD, according to one embodiment. The apparatus 200 includes, among other components, a first injector 210, a second injector 220, a vacuum gauge 214, a susceptor 230, and an ICP (inductive coupled plasma) type remote-plasma generator 250. These components are at least partially enclosed in a chamber 228. The susceptor 230 has recesses for holding one or more substrates 270. In one embodiment, each recess has a depth of 0.5 mm for receiving 2-inch substrates and/or 3-inch substrates. The susceptor 230 is rotated using a motor 234 (and gears) placed beneath the susceptor 230. The substrates 270 may be circular shaped or may take other shapes (e.g., rectangular).

In the apparatus 200, the substrates 270 are exposed to different chemicals (e.g., source precursor, reactant precursor, purge gas and the radicals of inert gas) as the substrates pass the injectors 210, 220. Compared to pumping out and injecting the entire chamber 228 with different chemicals, the use of injectors 210, 220 and relative movement between the substrates 270 and the injectors 210, 220 allow faster depositing of layers and conserve the chemicals used in the process while retaining high conformal quality of the deposited layers.

The first injector 210 injects one or more of source precursor, reactant precursor and radicals of inert gas onto the substrate 270 to deposit one or more layers of molecules on the substrate 270 that passes below the first injector 210. The second injector 220 also injects one or more of source precursor, reactant precursor and radicals of inert gas onto the substrate 270. In one embodiment, the second injector 220 performs step 126 of FIG. 1 by injecting the radicals of inert gas. For this purpose, the second injector includes a remote plasma generator, as described below in detail with reference to FIG. 3. The injectors 210 and 220 are enclosed within the chamber 228 that may be maintained in a vacuum state by pumping gas from the interior of the chamber 228. The vacuum gauge 214 measures the pressure within the chamber 228.

The ICP remote-plasma generator 250 may include, among other components, a quartz tube 254 and a coil 258 wound around the quartz tube 254 for generating plasma. The ICP remote-plasma generator 250 receives gas and generates plasma by applying a electric current across a coil. Various other types of plasma generator other than ICP remote-plasma generate may also be used.

As the susceptor 230 rotates, the substrates 270 pass below the first injector 210 and then the second injector 220 and finally the quartz tube 63 for the purpose of radical treatment. As the substrates 270 pass below the injector 210, the substrates 270 are first exposed to the source precursor. Part of the source precursor is absorbed into the surface of the substrates 270 or previously deposited layer on the substrate 270. Then, the substrates 270 are exposed to a purge gas (e.g., Argon) to remove any excess source precursor molecules from the surface. The excess source precursor refers to source precursor molecules that are physisorbed (but not chemisorbed molecules) on the substrates 270 or the deposited layer. As the substrates 270 further rotate, the substrates 270 are exposed to reactant precursor that form an atomic layer on the substrate.

The substrates 270 may be further injected with purge gas to remove any excess reactant precursor molecules from the surfaces of the substrates 270. The excess reactant precursor refers to reactant precursor molecules that are physisorbed (but not chemisorbed) on the substrates 270 or the deposited layer.

Alternatively, the reactant precursor may be provided by the second injector 220 instead of the first injector 210. The susceptor 270 may rotate in a direction indicated by arrows in FIG. 1 but can also rotate in a reverse direction or alternate the rotating direction to expose the substrates to different materials. In one embodiment, the first injector 210 performs steps 110 through 122 illustrated in FIG. 1.

As the susceptor 230 rotates further, the substrates 270 pass below the second injector 220. The second injector 220 injects radicals of inert gas (e.g., Ar) and/or reactants onto the surface of the substrates 270. The reactants may react with the source precursor material or replace the source precursor material deposited on the substrate to form a layer of deposited material.

In one embodiment, the second injector 220 includes a coaxial capacitive type plasma generator for generating the radicals of the inert gas, as described below in detail with reference to FIG. 3. Other types of plasma generator such as ICP (induction coupled plasma) may also be used instead of the coaxial capacitive type plasma generator. Subsequently, the substrates 270 may or may not be treated with the plasma generated by the ICP remote-plasma generator. Then, as the substrates 230 rotate further, the substrates 270 again passes below the first injector 210 to undergo another cycle of ALD.

The processes may also be performed in other types of apparatuses. Instead of using a susceptor that rotates, the susceptor may make a linear back-and-forth movement to deposit multiple layers of materials. Alternatively, the injectors may be in a tubular form adapted to deposit layers of materials on a curved surface.

FIG. 3 is a cross-sectional view of the injector 220 of FIG. 2, according to one embodiment. The injector 220 may include, among other components, a body 310, an outer electrode 320 and an inner electrode 330. A cavity 340 is formed between the outer electrode 320 and the inner electrode 330 where gas is provided via valves V₁, V₂ and V₃. The gas supplied to the cavity 120 may be varied by opening or closing valves V₁ and V₂, and may include inert gas (Ar) or reactant gas such as O₂, H₂ or NH₃. Valve V₃ controls the flow rate of gas into the cavity 340.

Both electrodes 320 and 330 extend along the length of the injector 220. Each of the electrodes 320 and 330 are coupled to a different terminal of a high voltage source. In one embodiment, a voltage of 500V to 1500V is applied across the outer electrode 320 and the inner electrode 330 to generate plasma within the cavity 340. The generated plasma passes slits 350 and is injected into an injection cavity 360. The width of the slits 350 may be 2 mm or more. The distance between the bottom of the cavity 340 and the substrate 270 passing below the second injector 220 may be approximately 15 mm to 20 mm. The diameter of the outer electrode 320 is about 10 to 20 mm.

The injector 220 may receive inert gas (e.g., Ar) within the cavity 340. When voltage is applied across the inner and outer electrodes 320, 330, radicals of the inert gas (e.g., Ar*) are generated in the cavity 340. The radicals of inert gas are then injected through the slit 350 to treat the surface of the substrate.

The injector 220 may receive reactant gas such as O₂, H₂ or NH₃ instead of the inert gas to generate the radicals of the reactant gas (e.g., O* radicals, H* radicals or N* radicals).

While a portion of the substrate 270 passes the injection cavity 360, the portion of the substrate 270 is exposed to the radicals of the inert gas or the reactant gas. After the radicals are injected onto the substrate via the cavity 340, the radicals pass a constriction zone 364 and are then exhausted through an exhaust zone 368 formed in the body 310 of the injector 220. Note that radicals with short lifespan (e.g., Ar* radicals, H* radicals or N* radicals) may also function as a purge gas after these radicals revert back to an inert state. At least part of the reactant molecules or radicals absorbed on the surface of the substrate is desorbed from the substrate by the radicals when passing through the constriction zone 364. That is, after being injected onto the surface of the substrate, the radicals may revert back to the inert state after a short period. The inert gas may then function as a purge gas that removes excess reactant from the surface of the substrate.

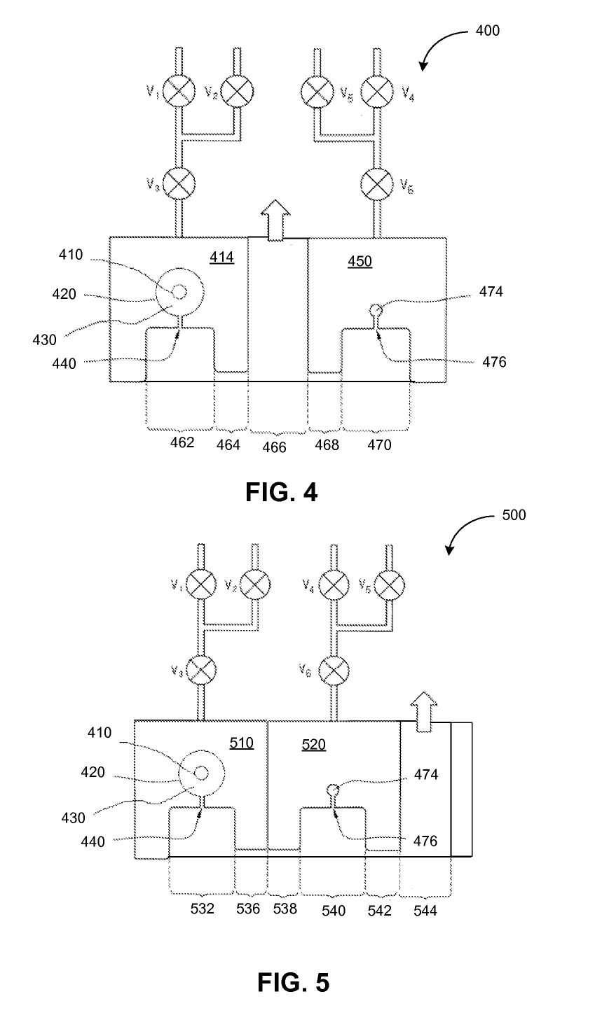

FIG. 4 is a cross-sectional diagram illustrating an injector 400 with a remote plasma generator 414 and a gas injector 450, according to one embodiment. Inert gas Reactant precursor gas such as O₂, N₂O, H₂ and NH₃ is injected via valve V₁ into the remote plasma generator 414 while inert gas (e.g., Ar or He) is injected via valve V₂ into the remote plasma generator 414. In one embodiment, the gas supplied to the remote plasma generator 414 is alternated by controlling turning on or off valves V₁ and V₂. The remote plasma generator 414 includes an inner electrode 410 and an outer electrode 420. Between the inner electrode 410 and the outer electrode 420, the cavity 430 is formed to hold the gas injected through valve V₃. Valve V₃ controls the supply of mixed gas of reactant precursors and the inert gas into the cavity 430.

When the radicals of reactant precursor are generated at the remote plasma generator 414, the radicals of the reactant precursor gas are injected via slits 440 onto the substrate, and absorbed in the substrate 270 via cavity 462. As the reactant precursor gas passes the constriction zone 464, part of the reactant molecule or radicals absorbed in the substrate 270 is stripped away and discharged via the exhaust portion 466. As described above in detail with reference to FIG. 3, when the radicals of inert gas is generated at the remote plasma generator 414, the radicals may perform surface treatment and then function as purge gas after reverting to an inert state.

The gas injector 450 injects purge gas or other gases onto the surface of the substrate 270. Valves V₄ and V₅ are turned on or off to provide a certain type of gas to the gas injector 450. The amount of gas provided to the gas injector 450 may be controlled by valve V₆. The gas provided to the gas injector 450 include, for example, source precursor, reactant precursor or purge gas. The gas injector 450 has a gas channel 474 extending longitudinally and connected to valve V₆ for providing the gas into cavity 470 via multiple holes or slits 476. The purge gas injected onto the surface the substrate 270 further removes excess source precursor, reactant precursor or radicals not removed by the remote plasma generator 414.

If purge gas is provided to the gas injector 450, the gas injector 450 may perform purging operation to remove reactant precursor molecules or source precursor molecules from a portion of the substrate 270 as the portion of the substrate 270 passes the constriction zone 468. The excess gases are discharged via the exhaust zone 466.

FIG. 5 is a cross-sectional diagram illustrating an injector 500 with a remote plasma generator 510 and a purge gas injector 520, according to another embodiment. The injector 500 is similar to the injector 400 except that an exhaust portion 544 is provided at the end of the injector and the constriction zone is longer than the embodiment of FIG. 3A. The injector 500 may include, among other components, a plasma generator 510 and a gas injector 520 that abut each other. In the injector 500, cavity 532, constriction zones 536 and 538, cavity 540, construction zone 542 and the exhaust portion 544 are formed sequentially at the bottom portion of the injector.

The remote plasma generator 510 generates the radicals of inert gas and performs surface treatment on a portion of the substrate 270 passing below the cavity 532 as the substrate 270 moves from left to right direction in FIG. 5. The radicals of inert gas reverts to inert state by the time the inert gas passes through the constriction zones 536 and 538, thereby removing excess radicals from a portion of the substrate 270 passing below the constriction zones 536 and 538. The gas injector 520 provides additional inert gas onto the surface of the substrate 270 to further remove excess molecules or radicals from the surface of the substrate 270.

In one embodiment, the pressure in cavity 532 is higher than the pressure in cavity 540 to avoid back flow of the gases into cavity 532. Alternatively, the flow rate of the gas through the holes 440 should be higher than the flow rate of the gas through the holes 476.

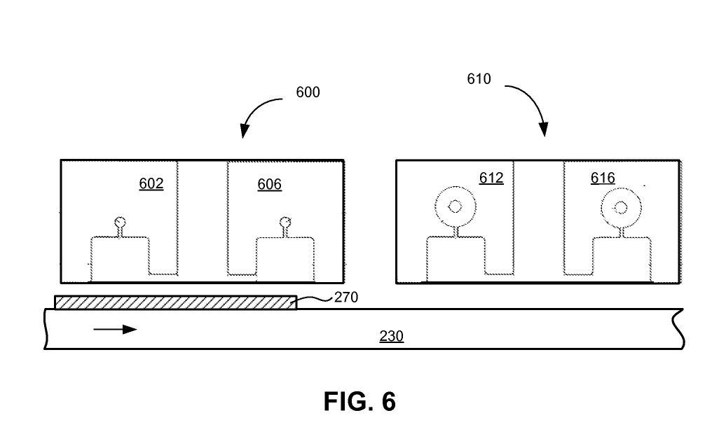

FIG. 6 is a diagram illustrating injectors 600, 610 for forming a deposited layer on the substrate, according to one embodiment. The injector 600 includes two gas injectors 602, 606, each having a body with a gas channel and multiple slits. As the substrate passes below the gas injector 602, source precursor (e.g., Trimethylaluminium (TMA)) is injected onto the substrate 270. Source precursor is partly absorbed in the substrate 270 as a result. In one embodiment, Argon is used as carrier gas for injecting the source precursor (e.g., TMA). The Argon gas is provided at 10 sccm, and stored in canister at the temperature of 3° C. As the substrate passes below the gas injector 606, the substrate 270 is then subject to the purge gas (e.g., Ar) to remove excess source precursor from the substrate 270.

The remote plasma generator 612 of the injector 610 is provided with gas (e.g., O₂) to generate radicals (e.g., O* radials) by applying voltage across electrodes in the remote plasma generator 612. The radicals generated at the injector 612 function as reactor precursor. In one embodiment, voltage of 1000V at 50W to 200W is applied across electrodes in the remote plasma generator 612. The radicals are formed within the remote plasma generator 612 and are injected onto the substrate 270. As the radicals from the remote plasma generator 612 react with or replace the source precursor molecules on the substrate 270, a deposited layer (e.g., Al₂O₃) is formed on the substrate 270.

The substrate 270 with the deposited layer then passes under a second remote plasma generator 616 of the injector 610. The second remote plasma generator 616 generates plasma of an inert gas (e.g., Ar) by applying voltage across two electrodes in the second remote plasma generator 616. By exposing the substrate 270 to the radicals of the inert gas, the surface state of the substrate appears to change, for example, by disconnecting bonds and causing these molecules to have dangling bonds. Taking the example of Al₂O₃ as the deposited layer, the exposure to the radicals of the inert gas disconnects Al—O bonds. Hence, when the substrate 270 is again injected with the source precursor by the injector 602 in the next cycle, the absorption coefficient and the reaction coefficient of the surface increase. The increased absorption coefficient and the reaction coefficient results in increased deposition rate in ALD. Further, layers formed by treating the surface of substrate 270 also results in higher quality (e.g., density).

In one or more embodiments, the substrate 270 is injected with the source precursor within 6 seconds after being surface treated with the radicals of the inert gas. In some embodiments, the substrate 270 is injected with the source precursor within 3 seconds after being surface treated with the radicals of the inert gas. By exposing the substrate 270 to the source precursor within a short time, the surface of the substrate 270 is exposed to the source precursor while the surface of the substrate 270 retains the high absorption coefficient and reaction coefficient. The increased absorption coefficient and reaction coefficient contributes to higher deposition rate.

Furthermore, ALD layers formed by surface treating the surface with the radicals of the inert gas exhibits other advantageous properties compared to ALD layers formed without surface treatment with the radicals of the inert gas. For example, Al₂O₃ formed by surface treating the surface with radicals of Ar gas has higher density and a higher index of optical refraction compared to Al₂O₃ formed without surface treatment suing the radicals of Ar gas.

Although the present invention has been described above with respect to several embodiments, various modifications can be made within the scope of the present invention. Accordingly, the disclosure of the present invention is intended to be illustrative, but not limiting, of the scope of the invention, which is set forth in the following claims.

What is claimed is:

1. A method of depositing one or more layers of material on a substrate, comprising:
exposing a surface of the substrate to a first material;
exposing the surface of the substrate exposed to the first material to a second material;
exposing the surface of the substrate exposed to the second material to radicals of inert gas to treat the surface of the substrate; and
exposing the treated surface of the substrate to a third material.

2. The method of claim 1, further comprising removing excess second material from the surface of the substrate by purge gas reverted to an inert state from the radicals of the inert gas.

3. The method of claim 1, wherein the third material is identical to the first material.

4. The method of claim 3, wherein the first material and the third material are source precursor for atomic layer deposition (ALD) and the second material is a reactant precursor for the ALD.

5. The method of claim 3, wherein the first material comprise source precursor and the second material comprises radicals reacting with the source precursor to form a thin film.

6. The method of claim 1, further comprising:
exposing the surface of the substrate to purge gas to remove excess source precursor on the surface after exposing the surface of the substrate to the source precursor and before exposing the surface to the reactant precursor; and
exposing the surface to purge gas to remove excess reactant precursor on the surface after exposing the surface to the reactant precursor and before exposing the surface to the radicals of the inert gas.

7. The method of claim 1, wherein the surface of the substrate is exposed to the third material within 6 seconds after being exposed to the radicals of the inert gas.

8. The method of claim 1, further comprising rotating a susceptor mounted with the substrate in a vacuum chamber, wherein the surface of the substrate is exposed to the first material, the second material, the radicals of the inert gas and the third material as the susceptor rotates with the substrate.

9. An article comprising one or more layers of materials deposited on a surface, the one or more layers formed by a method comprising:
exposing the surface to a first material;
exposing the surface exposed to the source precursor to a second material;
exposing the surface exposed to the reactant precursor to radicals of inert gas to treat the surface; and
exposing the treated surface to a third material.

10. The article of claim 9, wherein the method further comprises removing excess second material from the surface by purge gas reverted to an inert state from the radicals of the inert gas.

11. The article of claim 9, wherein the third material is identical to the first material.

12. The article of claim 11, wherein the first material and the third material are source precursor for atomic layer deposition (ALD) and the second material is a reactant precursor for the ALD.

13. The article of claim 11, wherein the first material comprise source precursor and the second material comprises radicals reacting with the source precursor to form a thin film.

14. The article of claim 9, wherein the method further comprises:
exposing the surface to purge gas to remove excess source precursor on the surface after exposing the surface to the source precursor and before exposing the surface to the reactant precursor; and
exposing the surface to purge gas to remove excess reactant precursor on the surface after exposing the surface to the reactant precursor and before exposing the surface to the radicals of the inert gas.

15. The article of claim 9, wherein the surface of the substrate is exposed to the third material within 6 seconds after being exposed to the radicals of the inert gas.

16. An apparatus for performing deposition of one or more layers of material on a substrate, comprising:
a first device configured to inject a reactant precursor on a surface of a substrate;
a second device configured to generate radicals of inert gas by applying voltage across at least two electrodes and configured to inject the radicals onto the surface of the substrate injected with the reactant precursor; and
a third device configured to inject a source precursor on the surface of the substrate injected with the radicals of the inert gas.

17. The apparatus of claim 16, where the second device is formed to include a constriction zone through which purge gas including inert gas reverted to an inert state from the radicals to remove excess reactant precursor from the surface of the substrate.

18. The apparatus of claim 16, further comprising:
a susceptor configured to hold the substrate; and
an actuator configured to cause relative movement between the susceptor, the first device, the second device and the third device.

19. The apparatus of claim 18, wherein the first device, the second device, the third device and the susceptor are enclosed in a vacuum chamber.

20. The apparatus 16, wherein the first device comprises a remote plasma generator configured to generate radicals of a material as the reactant precursor and inject the generated radicals of the material onto the surface of the substrate.
